(19) United States
(12) Patent Application Publication
(10) Pub. No.: US 2026/0115826 A1
(43) Pub. Date: Apr. 30, 2026

(54) MACHINE VISION POSITIONING AND ALIGNMENT OF WAFERS FOR APPLICATION OF LASING PATTERNS

(71) Applicant: II-VI Delaware, Inc., Wilmington, DE (US)

(72) Inventors: Xiquan Wu, Suzhou (CN); Toby David Rule, Bremerton, WA (US)

(21) Appl. No.: 18/937,787

(22) Filed: Nov. 5, 2024

(30) Foreign Application Priority Data
Oct. 31, 2024 (CN) 2024115451214

(51) Int. Cl. B23K 26/03; B23K 26/082; B23K 101/40; G02B 26/10; H01L 21/268

(52) U.S. Cl. CPC B23K 26/032; B23K 26/082; G02B 26/105; H10P 34/42; B23K 2101/40

(57) ABSTRACT

Systems and methods are provided for utilizing machine vision positioning and alignment of wafers for application of lasing patterns. A laser annealing machine that is configured to apply laser annealing to workpieces, may be configured to provide visual positioning and alignment of workpieces for the application of laser annealing. Providing visual positioning and alignment of workpieces includes obtaining, via at least one visual sensing device, visual data representative of a workpiece, identifying, based on the obtained visual data, one or more features or regions in the workpiece, to ensure that the workpiece is centered and aligned when applying the scanning beam to the workpiece. The identifying includes adjusting operation of at least one processing component.

### CLAIM OF PRIORITY

This patent application claims priority to and claims benefit from Chinese (CN) patent application No. 2024115451214, filed on Oct. 31, 2024. The above identified application is hereby incorporated herein by reference in its entirety.

### TECHNICAL FIELD

Aspects of the present disclosure relate to device fabrication (e.g., semiconductor wafers) related solutions. More specifically, certain implementations of the present disclosure relate to methods and systems for implementing and utilizing machine vision positioning and alignment of wafers for application of lasing patterns.

### BACKGROUND

Limitations and disadvantages of conventional and traditional solutions will become apparent to one of skill in the art, through comparison of such systems with some aspects of the present disclosure as set forth in the remainder of the present application with reference to the drawings.

### BRIEF SUMMARY

System and methods are provided for machine vision positioning and alignment of wafers for application of lasing patterns, substantially as shown in and/or described in connection with at least one of the figures, as set forth more completely in the claims.

These and other advantages, aspects and novel features of the present disclosure, as well as details of an illustrated embodiment thereof, will be more fully understood from the following description and drawings.

### BRIEF DESCRIPTION OF THE DRAWINGS

FIG. 1 illustrates an example laser annealing machine.

FIG. 2 illustrates an example use case when utilizing a video mode of laser control software in an example laser annealing machine.

FIGS. 3A-3B illustrate example images captured using integrated visual detection system in an example laser annealing machine.

FIGS. 4A-4B illustrate an example use case when center offset and rotation alignment is performed.

### DETAILED DESCRIPTION

The present disclosure is directed to device fabrication (e.g., semiconductor wafers) related solutions. In particular, implementations based on the present disclosure are directed to visual-based positioning and alignment of workpieces (e.g., wafers) during annealing processing (e.g., when applying lasing patterns). In various implementations based on the present disclosure, workpiece positioning and alignment may be done by use of visual data (e.g., images) obtained via visual sensing devices (e.g., cameras) to ensure proper positioning and alignment of the workpiece during processing (e.g., annealing) of the workpiece, with the positioning and alignment related adjustments being determined and made automatically—e.g., by software in the system. In some instances, workpiece positioning and alignment may be done using, e.g., stage motion or galvanometer motion. This may be particularly the case in processing systems (e.g., laser annealing machines) that utilize galvanometric scanning. In such machines, hardware and software are used for laser annealing, thus essentially forming a laser engraving system that is adapted for the annealing applications. In machines using galvanometric scanning, one or more galvanometer mirrors (also referred to herein as “galvo mirrors”) may be used to control the scanning beams that are used for the laser annealing. In some instances, the galvo mirrors may be movable, such as using corresponding galvanometer (galvo) motors. For example, a collimated laser beam first passes through one or more (e.g., two) galvo mirrors that steer the beam in two dimensions. In some instances, additional optical components may be used, such as to focus the scanning beam onto the surface of the workpiece, thus providing the desired scanning (annealing). For example, the scanning beam may be focused using one or more lenses (e.g., telecentric lenses).

In various implementations, the workpiece surface may be viewed using a camera. In some instances, the camera may collect light through the same optics that are used to direct and focus the laser beam. Such camera may be used to collect images for manual positioning, or for machine vision alignment of the workpiece. In some instances, the camera may be coaxial camera—that is, having the same orientation as the component used in projecting the scanning beam.

In various implementations, machine vision is utilized to ensure workpiece positioning and alignment. In this regard, machine vision alignment requires capturing precise image data, particularly around the edge(s) of the workpiece, detecting the workpiece edge, and aligning the scan pattern with the detected edge. Doing so may be challenging in some instances, such as due to the size considerations. In this regard, the typical workpiece is circular, ranging in size, e.g., from around 100 mm diameter to 200 mm diameter or more, with a flat on one side. However, the field of view through the coaxial camera may be much smaller (e.g., only about 4 mm), and as such multiple images may need to be captured at different locations. Hence, alignment points are specified along the circular edge, and along the wafer flats. The stage is moved to each alignment point and an image is captured at that point using the coaxial camera.

An edge detection algorithm may be used to identify the edge pixels in each image. The edge pixels on the circular edge of the workpiece are used to align the scan pattern (e.g., by offsetting one or both of the x-position and the y-position within an x-y plane that corresponds to the flat surface of the workpieces), and the edge pixels along the flat side are used to align the scan pattern rotationally. As such, due to the necessity of moving the stage to each alignment point, even with smaller workpieces (e.g., 100 mm diameter or less) the alignment process may take a significant amount of time. In the case of laser annealing, the alignment process may be especially slow, because the workpieces may be large (e.g., 200 mm in diameter or larger). In some instances, the x-axis of the x-y stage (or both x-axis and y-axis), may be deleted, because the motion axes are not necessary with a single chamber and a scan lens with a wide scan area.

Accordingly, reducing the complexity and time required for performing workpiece positioning and alignment, particularly for laser annealing, is desirable. In various implementations based on the present disclosure galvo motion-based workpiece positioning and alignment may be used. In this regard, for the reasons set forth above, alignment using galvo motion may be preferred. In order to speed up the workpiece positioning and alignment process, the camera may be aimed using the galvo mirrors instead of by stage positioning. This may be done by configuring existing software used in the machine for controlling laser-related functions. For example, such software may be configured to use a special mode (e.g., a “galvo positioning mode”) that is adaptively configured for enabling automatic positioning and alignment based on images captured in the machine, such as the coaxial camera described herein. Various aspects of solutions in accordance with the present disclosure and implementations based thereon are described in more detail below with respect to the figures.

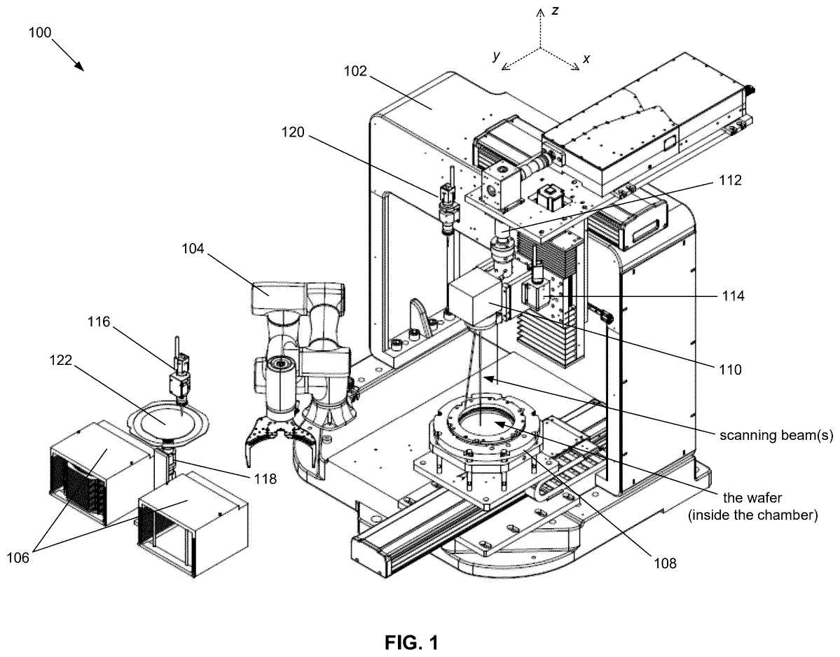

FIG. 1 illustrates an example laser annealing machine. Shown in FIG. 1 is a laser annealing machine (or simply “machine”) 100 (or a portion thereof), implemented in accordance with an example embodiment.

The machine 100 is configured for use in treating semiconductor wafers using laser annealing. In this regard, annealing is a heat treatment that may be used to alter the physical and/or chemical properties of a material. Specifically, the heat treatment performed during annealing may be used, to achieve a condition to heat up the surface layer of material (usually very thin metal layer) to react with underlying bulk material (semiconductor) to form omhic contact on the backside of the wafer without heating up the front side devices. In laser annealing a laser beam is used for the heat treatment. Laser annealing may be used during semiconductor device fabrication as one of the process steps used in fabricating a semiconductor device. In particular, laser annealing may be used to treat semiconductor wafers during semiconductor device fabrication.

The machine 100 comprises suitable hardware components and circuitry (e.g., embedded within dedicated control components (not shown) and/or within some of the hardware components of the machine) configured for facilitating laser annealing, particularly laser annealing of semiconductor-based wafers or the like.

As shown in FIG. 1, the machine 100 comprises a main structure 102, a robot arm 104, one or more wafer cassettes (containers) 106, an annealing chamber 108, a scan head 110, and a laser source 112.

The main structure 102 is configured to engage and/or house at least some of the remaining components of the machine 100. For example, the main structure 102 may comprise a base section that securely supporting the remaining sections of the machine, chamber holding section (attached to or is part of the base section) that engages the annealing chamber 108, and a frame section configured to hold or engage the scan head 110 and the laser source 112 above the chamber holding section.

The scan head 110 may be configured to enable projecting laser beams emitted by the laser source 112 onto the wafer 122 within the annealing chamber 108. In various implementations, the scan head 110 may comprise optical components configured for enabling controlling and directing the laser beam emitted by the laser source 112, such that the beam may be projected (e.g., vertically—that is, downwards in the z-direction) onto the surface of the wafer 122 when placed within the annealing chamber 108. For example, the optical components comprise one or more mirrors (e.g., galvo mirrors) and one or more lenses (e.g., telecentric lenses). The scan head 112 may also comprise additional components that may be needed to control the optical components, such as galvo motors that may be used in moving the galvo mirrors. These optical components may be configured to operate collaboratively, to enable controlling the laser beam emitted by the laser source 112 (and inputted into the scan head 110), to enable re-directing the laser beam such that it may be projected downwards (vertically) onto the surface of the wafer 122), as shown in FIG. 1.

In some implementations, the frame section may incorporate a scanner holding section that holds or engages the scan head 110 and the laser source 112. Further, in some implementations one or both of the chamber holding section and the scanner holding section may be moveable (e.g., using rail-like mechanisms), to ensure aligning the scan head 110 and the annealing chamber 108. For example, the scan head 110 may be configured to move in one direction (e.g., x-direction) whereas the annealing chamber 108 may move in different direction (e.g., y-direction), to facilitating aligning the scan head 110 during scanning. Further, the scan head 110 may further be moveable in the z-direction—that is, up and down relative to the annealing chamber 108-such as to enable focusing. Accordingly, the scan head 110 may be effectively moved (e.g., by moving it directly, or by moving other components) in 3-dimensions relative to the annealing chamber 108.

In operation, the robot arm 104 is configured to retrieve (untreated) wafer 122 from one wafer cassette 106, and to place the wafer 122 into the annealing chamber 108. Once in the annealing chamber 108, the wafer 122 is treated, which includes subjecting the wafer to laser annealing. In this regard, the wafer 122 is treated by subjecting to scanning beam projected onto it from the scan head 110, with the laser source 112 providing the laser used in the scanning beam. For example, the scan head 110 may comprise a mirror positioned at suitable angle (e.g., 45°) to enable projecting the laser beam(s) emitted by the laser source 112 downwards (e.g., vertically, at 90° relative to the horizontal plane) onto the wafer 122 inside the annealing chamber 108, thus providing the scanning beam. Once the laser annealing is completed, the robot arm 104 retrieves the treated wafer 122 from the annealing chamber 108 and places it back (e.g., into another wafer cassette 106).

In accordance with the present disclosure, laser annealing machines (e.g., the machine 100) may incorporate an integrated visual detection system that may be configured for providing and/or supporting various visual-based functions that may be used in enhancing operation and/or performance of the laser annealing machines. In this regard, an example integrated visual detection system may comprise one or more visual sensing devices (e.g., cameras) that may be used providing and/or supporting performing visual-based functions in the machine, such as visual-based control, visual-based monitoring, visual-based inspections, etc.

For example, in the embodiment illustrated in FIG. 1, the machine 100 comprises a plurality of cameras comprising a coaxial camera 114, a top inspection camera 116, and a bottom inspection camera 118. The machine 100 may further comprise a main camera 120. Each of these cameras may comprise suitable hardware components (e.g., lenses, etc.) and circuitry, which may be configured to enable capturing or otherwise obtaining visual representations (e.g., still images, video, etc.), such as of particular objects and/or specific areas thereof.

The coaxial camera 114 may be configured to obtain visual data of the wafer 122 while in annealing chamber 108, and particularly while being scanned using the scan head 112. In this regard, the coaxial camera 114 is arranged such that it has the same view orientation as the scan head 112—that is, the coaxial camera 114 obtains visual data (images) along an axis parallel to the scanning beam projected by the scan head 112. The top inspection camera 116 and the bottom inspection camera 118 may be configured to obtain visual data of, respectively, the top surface and bottom surface of each of the wafers 122 as wafers are retrieve from and/or loaded back into the wafer cassettes 106. The main camera 120 may be configured to obtain visual data of the wafer 122 while being handled within the machine 100—that is, while it is being handled by the robotic arm 104, while placed within the annealing chamber 108, etc. As such, the main camera 120 may allow for obtaining visual data of the wafer 122 in many aspects other than in a coaxial manner as provided by the coaxial camera 114.

In various implementations based on the present disclosure, such integrated visual detection systems may be configured to provide and/or support visual based positioning and alignment of wafers, and/or in facilitating use of process-control methods associated therewith. In particular, the integrated visual detection systems may be configured to provide and/or support performing visual-based positioning and alignment of wafers during processing of the wafers, such as to ensure proper and optimal positioning and alignment of wafers when applying lasing patterns thereto during annealing of wafers.

For example, the integrated visual detection system may be configured to sense and identify particular features (e.g., the edges and flat) of the wafer. These detected features may then be used (e.g., in software) to set and/or adjust the lasing patterns. In this regard, the scanning may be controlled by adjusting the software that drives scan related components (e.g., scanning lenses and/or optics, such as those within the scan head). Use of such simplified design may be advantageous over any existing solutions as it would allow for eliminating x-y stage movement—that is, movement in the x-y plane—thus reducing cost and complexity. Further, pre-orientation is not required with such simplified design, thus eliminating risks associated with handling of the wafers.

In various implementations, workpiece positioning and alignment may be performed using, e.g., stage motion or galvanometer motion. In this regard, as noted in laser annealing machines (e.g., the machine 100), annealing is performed by use of a laser engraving, with a collimated laser beam being used as a scanning beam to perform the annealing. The laser beam may be projected via the scan head 110. Where the galvanometric based design is used, the laser beam passes through one or more (e.g., two) galvo mirrors which are used to steer the beam (e.g., in two dimensions), and the beam is then focused onto the surface of the wafer (e.g., using a telecentric lens).

In accordance with the present disclosure, the coaxial camera 114 is used to obtain images of the surface of the wafer 122, with these images being used to enable alignment of the wafer 122. In particular, in order to speed up the process, the coaxial camera 114 may be configured to enable utilizing the galvo mirrors (e.g., rather than by x-y stage positioning in the plane). This may be done by configuring the machine 100 to support a dedicated mode (e.g., a “galvo positioning mode”) for use in such instances. In this regard, the machine 100 may comprise or otherwise use laser control software that is used for configuring and controlling the laser marking process. The laser control software may have or use multiple motion coordinate system modes, such as to account for different coordinate system offsets. These may comprise, for example, laser, video, touch probe, and depth sensor modes.

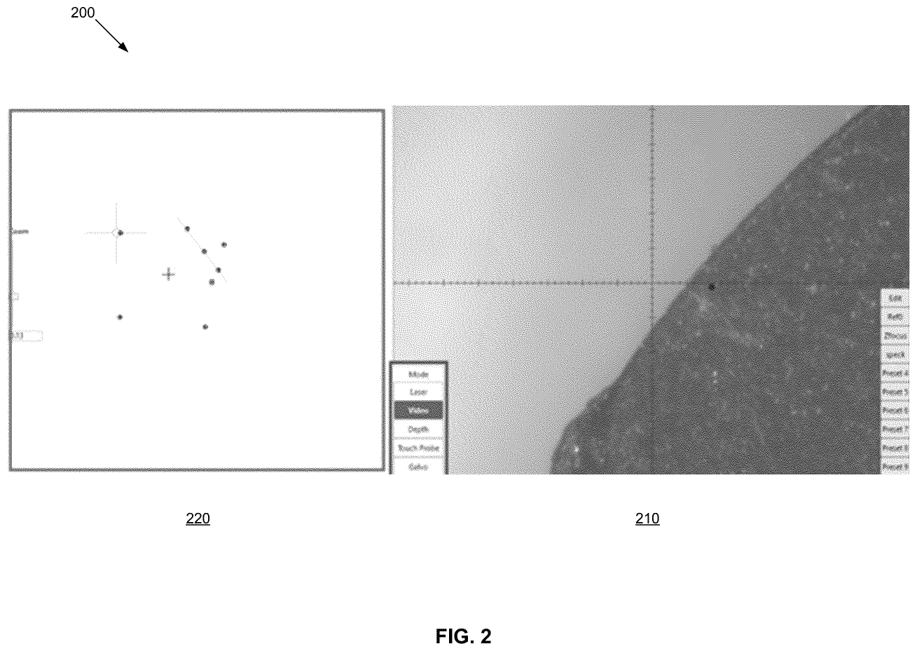

For example, when setting up the machine 100, it may be possible to manually position the camera view over different parts of the wafer, such as by switching a particular mode (e.g., a “video” mode). It may be then possible to focus on different areas within the image, such as by interacting with (e.g., by clicking on) different areas within an interface (e.g., a “cutting path” pane). The x-y stage may then move the workpiece so that this part of the pattern is in camera view. An example of such a manual process is illustrated in FIG. 2.

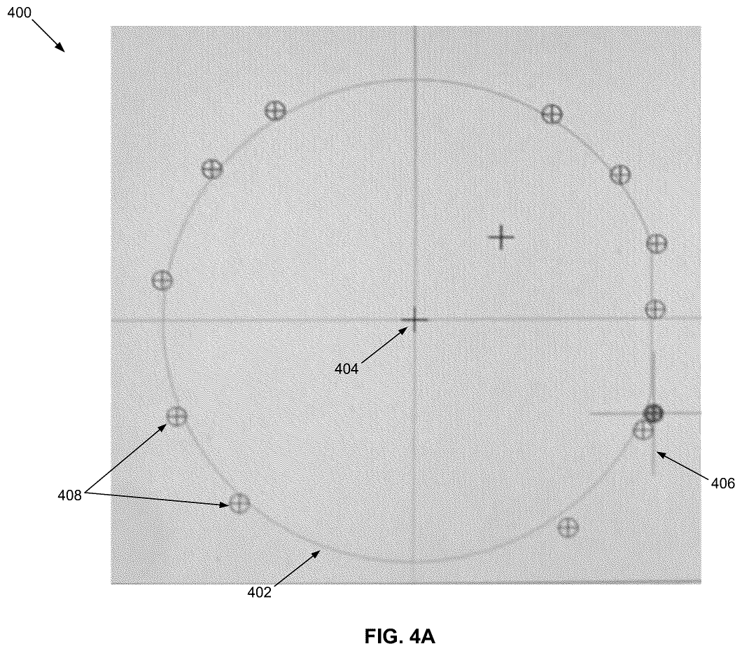

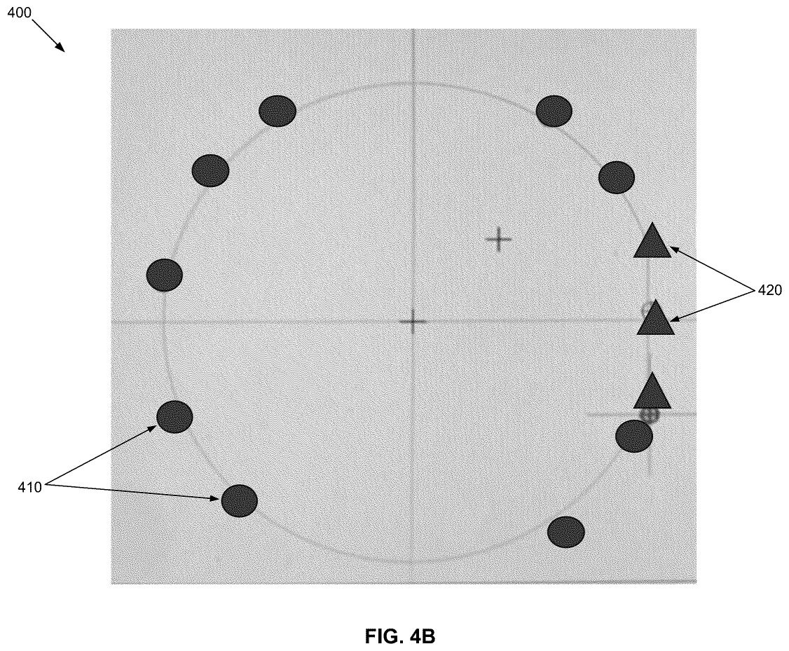

In accordance with the present disclosure, in order to handle alignment operations using the galvo mirrors, a galvo positioning mode may be added and used instead. In this regard, in response to switching to the galvo positioning mode (e.g., based on user input or the like), and optionally based on interacting with the image (e.g., by clicking on particular areas or points in the image within the “cutting path” pane), the galvo mirrors may be used to aim the camera at the particular region(s) of the wafer, without moving the x-y stage. This is handled and done by the laser control software. By performing video alignment in galvo positioning mode, it is possible to perform the alignment operations using the same sequence of operations as before, except that the camera is quickly aimed using the galvo mirrors, instead of being slowly positioned using x-y stage motion. This is illustrated in FIGS. 4A-4B. Such quick aiming of the camera results in improved performance as the positioning and alignment is completed in less time overall.

In some instances, additional measures may be used to account for any potential limitations with the use of a galvo positioning mode. For example, the range of motion in a galvo positioning mode may be limited—e.g., due to the range of galvo mirror angles that produce acceptable images of the surface. As such it may be necessary to introduce a scale correction factor when aiming the video using the galvo mirrors, because the center of the video field of view may not align perfectly with the laser focus point when it is aimed off-center. Accordingly, in some implementations, the laser annealing machine (e.g., the machine 100), or the laser control software used therein in particular, may be configured to determine and apply such scale correction factors.

FIG. 2 illustrates an example use case when utilizing a video mode of laser control software in an example laser annealing machine. Shown in FIG. 2 is screenshot 200 comprising two separate image sections 210 and 220.

In this regard, the screenshot 200 may correspond or illustrate a particular mode that may be supported in or used via a laser control software that may be utilized in an example laser annealing machine, such as the laser annealing machine 100 of FIG. 1. In particular, within the screenshot 200, the image section 210 illustrates an example “video” mode associated with the laser control software, whereas the image section 220 represents an example “cutting path” pane that may be used or be otherwise available via the laser control software in conjunction with the “video” mode. As noted, when setting up the laser annealing machine, it is possible to manually position the camera view over different parts of the wafer by switching to “video” mode (the image section 210), and then it may be possible to select particular areas within the view, such as by clicking on different areas within the “cutting path” pane (the image section 220). The x-y stage may then move the workpiece so that this part of the pattern is in camera view.

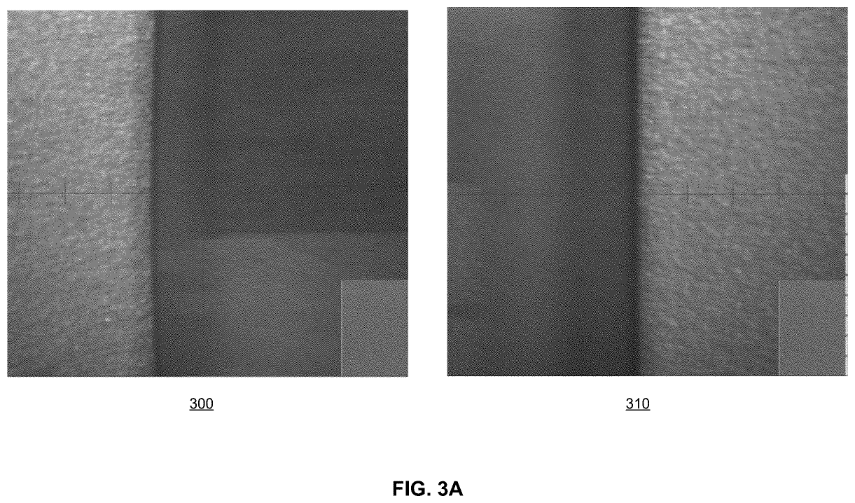

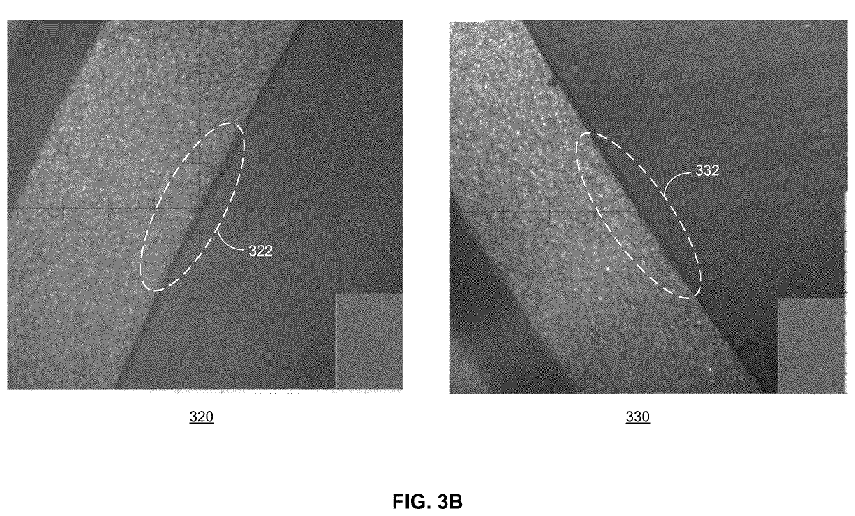

FIGS. 3A-3B illustrate example images captured using integrated visual detection system in an example laser annealing machine. Shown in FIGS. 3A-3B are images 300, 310, 320, and 330 that represent example images captured using an integrated visual detection system in a laser annealing machine (e.g., the machine 100).

In this regard, the laser annealing machine may be configured to utilize the integrated visual detection system in managing laser annealing processing. For example, with reference to the machine 100, the images 300-330 may be captured using the coaxial camera 114. In particular, images 300-330 represent images of particular wafer 122 and portions thereof (e.g., edge, transition area between central flat part and edge section, etc.), of a wafer while it is being processed within the annealing chamber 108, and particularly while alignment and/or positioning related processing is being performed in accordance with the present disclosure.

In this regard, the image 300 shows left edge of the wafer. The image 310 shows flat section of the wafer. The image 320 shows an edge section of the wafer, particularly illustrating a set of pixels (322) indicative of detection of wafer edge position for that edge section. Similarly, the image 330 shows different edge section of the wafer, particularly illustrating a set of pixels (332) indicative of detection of wafer edge position for that edge section.

FIGS. 4A-4B illustrate an example use case when center offset and rotation alignment is performed. Shown in FIGS. 4A-4B is an offset and alignment chart 400 which may be used during example center offset and rotation alignment in a laser annealing machine (e.g., the machine 100) configured to utilize an integrated visual detection system in managing laser annealing processing in accordance with the present disclosure.

The offset and alignment chart 400 may be configured and/or used to enable positioning (e.g., centering) and aligning wafers during processing in the laser annealing machine. In particular, the offset and alignment chart 400 may be used in conjunction with captured images (e.g., via the coaxial camera 114). For example, the offset and alignment chart 400 may be used via software in the system (e.g., laser control software), in conjunction with captured images, when wafer positioning and alignment related processing is performed. In this regard, the offset and alignment chart 400 may be, e.g., overlaid onto images of the wafer (or sections thereof) to enable positioning and/or aligning the wafer.

As shown in FIG. 4A the offset and alignment chart 400 may comprise a circle 402 having a center point 404. The offset and alignment chart 400 may comprise a tangent line 406 intersecting the circle 402 at one side (e.g., where the x-axis of the offset and alignment chart 400 intersect the circle 402). To facilitate positioning and/or aligning of the wafer, a plurality of alignment points 408, along the circumference of the circle 402 and the tangent line 406 may be used.

For example, the alignment points 408 may be used in conjunction with the galvo mirrors to facilitate the positioning and alignment of the wafer, as illustrated in FIG. 4B. During an example use case, circular alignment may be performed, for an offset wafer anneal program center position. This may be performed by having a galvo mirror (e.g., inside the scan head 112) move (e.g., along the circle 402) to enable checking and/or identifying a plurality of circular alignment locations 410 (e.g., different edge points along the circle 402). Rotational alignment may be the performed (e.g., for wafer anneal program orientation). This may be done by moving the galvo mirror (e.g., along the tangent line 406) to enable checking and/or identifying a plurality of linear alignment locations 420 on the wafer flat (e.g., along the tangent line 406), to enable calculating the wafer orientation.

An example system, in accordance with the present disclosure, comprises a laser annealing machine configured to apply laser annealing to workpieces, where the laser annealing machine comprises one or more handling components for handling the workpieces; one or more processing components configured for applying the laser annealing to the workpieces; an integrated visual detection system comprising one or more visual sensing devices configured to obtain visual data associated with the workpieces and/or the applying of the laser annealing to the workpieces; and control circuitry configured for controlling functions or operations of the laser annealing machine and/or one or more components of the laser annealing machine; where applying the laser annealing to each workpiece comprises applying a scanning beam onto a surface of the workpiece based on a scan pattern; where the laser annealing machine is configured to provide, via the control circuitry, visual positioning and alignment of workpieces for the application of laser annealing; and where providing visual positioning and alignment of workpieces comprises obtaining, via at least one visual sensing device, visual data representative of a workpiece; and identifying, based on the obtained visual data, one or more features or regions in the workpiece, to ensure that the workpiece is centered and aligned when applying the scanning beam to the workpiece, where the identifying comprises adjusting operation of at least one processing component.

In an example embodiment, the one or more processing components comprise one or more scanning components configured for projecting the scanning beam onto a workpiece while applying the laser annealing to the workpiece.

In an example embodiment, the one or more scanning components comprise a laser source configured to provide a laser beam for use in applying the laser annealing to the workpiece.

In an example embodiment, the one or more scanning components comprise a scan head configured to project the scanning beam onto the workpiece using an input beam received from a beam source.

In an example embodiment, the scan head comprises one or more optical components configured to directing the input beam to enable projecting the scanning beam onto the workpiece.

In an example embodiment, the one or more optical components comprise one or more galvanometer mirrors.

In an example embodiment, the at least one processing component is the scan head, where adjusting the operation of the at least one processing component comprises moving at least one galvanometer mirror.

In an example embodiment, the at least one processing component comprises a galvanometer mirror, where adjusting the operation of the at least one processing component comprises moving the galvanometer mirror.

In an example embodiment, the control circuitry is configured to run software for controlling the applying of the laser annealing, where the software is configured for enabling performing the visual positioning and alignment of workpieces.

In an example embodiment, configuring the software comprises modifying the software to support a dedicated mode for enabling adjusting the operation of the at least one processing component.

In an example embodiment, the dedicated mode comprises a galvo positioning mode when the at least one processing component comprises one or more galvanometer mirrors.

In an example embodiment, identifying the one or more features or regions in the workpiece comprises identifying a center of the workpiece.

In an example embodiment, identifying the center of the workpiece comprises identifying a plurality of circular alignment locations corresponding to different edge locations on the surface of the workpiece.

In an example embodiment, identifying the one or more features or regions in the workpiece comprises identifying an orientation of the workpiece.

In an example embodiment, identifying the orientation of the workpiece comprises identifying a plurality of linear alignment locations on the surface of the workpiece.

In an example embodiment, the at least one visual sensing device comprises a coaxial camera.

In an example embodiment, the one or more processing components comprise an annealing chamber configured to house a workpiece while applying the laser annealing to the workpiece.

In an example embodiment, one or more handling components comprise a robotic arm configured for moving the workpieces to facilitate the applying of the laser annealing.

In an example embodiment, one or more handling components comprise one or more containers configured for storage of the workpieces.

In an example embodiment, the workpieces comprise semiconductor wafers.

As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.” As utilized herein, the term “exemplary” means serving as a non-limiting example, instance, or illustration. As utilized herein, the terms “for example” and “e.g.” set off lists of one or more non-limiting examples, instances, or illustrations.

As utilized herein the terms “circuits” and “circuitry” refer to physical electronic components (e.g., hardware), and any software and/or firmware (“code”) that may configure the hardware, be executed by the hardware, and or otherwise be associated with the hardware. As used herein, for example, a particular processor and memory (e.g., a volatile or non-volatile memory device, a general computer-readable medium, etc.) may comprise a first “circuit” when executing a first one or more lines of code and may comprise a second “circuit” when executing a second one or more lines of code. Additionally, a circuit may comprise analog and/or digital circuitry. Such circuitry may, for example, operate on analog and/or digital signals. It should be understood that a circuit may be in a single device or chip, on a single motherboard, in a single chassis, in a plurality of enclosures at a single geographical location, in a plurality of enclosures distributed over a plurality of geographical locations, etc. Similarly, the term “module” may, for example, refer to a physical electronic component (e.g., hardware) and any software and/or firmware (“code”) that may configure the hardware, be executed by the hardware, and or otherwise be associated with the hardware.

As utilized herein, circuitry or module is “operable” to perform a function whenever the circuitry or module comprises the necessary hardware and code (if any is necessary) to perform the function, regardless of whether performance of the function is disabled or not enabled (e.g., by a user-configurable setting, factory trim, etc.).

Other embodiments of the invention may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the processes as described herein.

Accordingly, various embodiments in accordance with the present invention may be realized in hardware, software, or a combination of hardware and software. The present invention may be realized in a centralized fashion in at least one computing system, or in a distributed fashion where different elements are spread across several interconnected computing systems. Any kind of computing system or other apparatus adapted for carrying out the methods described herein is suited. A typical implementation may comprise one or more application specific integrated circuit (ASIC), one or more field programmable gate array (FPGA), and/or one or more processor (e.g., x86, x64, ARM, PIC, and/or any other suitable processor architecture) and associated supporting circuitry (e.g., storage, DRAM, FLASH, bus interface circuits, etc.). Each discrete ASIC, FPGA, Processor, or other circuit may be referred to as “chip,” and multiple such circuits may be referred to as a “chipset.” Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to perform processes as described in this disclosure. Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to be configured (e.g., to load software and/or firmware into its circuits) to operate as a system described in this disclosure.

Various embodiments in accordance with the present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system is not limited to the particular implementations disclosed, but that the present method and/or system will include all implementations falling within the scope of the appended claims.

What is claimed is:

1. A system comprising:
a laser annealing machine configured to apply laser annealing to workpieces, wherein the laser annealing machine comprises:
one or more handling components for handling the workpieces;
one or more processing components configured for applying the laser annealing to the workpieces;
an integrated visual detection system comprising one or more visual sensing devices configured to obtain visual data associated with the workpieces and/or the applying of the laser annealing to the workpieces; and
control circuitry configured for controlling functions or operations of the laser annealing machine and/or one or more components of the laser annealing machine;
wherein applying the laser annealing to each workpiece comprises applying a scanning beam onto a surface of the workpiece based on a scan pattern;
wherein the laser annealing machine is configured to provide, via the control circuitry, visual positioning and alignment of workpieces for the application of laser annealing; and
wherein providing visual positioning and alignment of workpieces comprises:
obtaining, via at least one visual sensing device, visual data representative of a workpiece; and
identifying, based on the obtained visual data, one or more features or regions in the workpiece, to ensure that the workpiece is centered and aligned when applying the scanning beam to the workpiece, wherein the identifying comprises adjusting operation of at least one processing component.

2. The system of claim 1, wherein the one or more processing components comprise one or more scanning components configured for projecting the scanning beam onto a workpiece while applying the laser annealing to the workpiece.

3. The system of claim 2, wherein the one or more scanning components comprise a laser source configured to provide a laser beam for use in applying the laser annealing to the workpiece.

4. The system of claim 2, wherein the one or more scanning components comprise a scan head configured to project the scanning beam onto the workpiece using an input beam received from a beam source.

5. The system of claim 4, wherein the scan head comprises one or more optical components configured to directing the input beam to enable projecting the scanning beam onto the workpiece.

6. The system of claim 5, wherein the one or more optical components comprise one or more galvanometer mirrors.

7. The system of claim 6, wherein the at least one processing component is the scan head, and wherein adjusting the operation of the at least one processing component comprises moving at least one galvanometer mirror.

8. The system of claim 1, wherein the at least one processing component comprises a galvanometer mirror, and wherein adjusting the operation of the at least one processing component comprises moving the galvanometer mirror.

9. The system of claim 1, wherein the control circuitry is configured to run software for controlling the applying of the laser annealing, and wherein the software is configured for enabling performing the visual positioning and alignment of workpieces.

10. The system of claim 9, wherein configuring the software comprises modifying the software to support a dedicated mode for enabling adjusting the operation of the at least one processing component.

11. The system of claim 10, wherein the dedicated mode comprises a galvo positioning mode when the at least one processing component comprises one or more galvanometer mirrors.

12. The system of claim 1, wherein identifying the one or more features or regions in the workpiece comprises identifying a center of the workpiece.

13. The system of claim 12, wherein identifying the center of the workpiece comprises identifying a plurality of circular alignment locations corresponding to different edge locations on the surface of the workpiece.

14. The system of claim 1, wherein identifying the one or more features or regions in the workpiece comprises identifying an orientation of the workpiece.

15. The system of claim 14, wherein identifying the orientation of the workpiece comprises identifying a plurality of linear alignment locations on the surface of the workpiece.

16. The system of claim 1, wherein the at least one visual sensing device comprises a coaxial camera.

17. The system of claim 1, wherein the one or more processing components comprise an annealing chamber configured to house a workpiece while applying the laser annealing to the workpiece.

18. The system of claim 1, wherein one or more handling components comprise a robotic arm configured for moving the workpieces to facilitate the applying of the laser annealing.

19. The system of claim 1, wherein one or more handling components comprise one or more containers configured for storage of the workpieces.

20. The system of claim 1, wherein the workpieces comprise semiconductor wafers.
